(19) United States
(12) Patent Application Publication
(10) Pub. No.: US 2010/0071623 A1
(43) Pub. Date: Mar. 25, 2010

(54) EVAPORATING APPARATUS

(75) Inventors: Shingo Watanabe, Hyogo (JP); Yuji Ono, Hyogo (JP); Koyu Hasegawa, Hyogo (JP); Masahiro Ogawa, Hyogo (JP); Kouichi Honda, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/441,934

(22) PCT Filed: Oct. 1, 2007
(86) PCT No.: PCT/JP2007/069187

§ 371 Date: Mar. 19, 2009

(30) Foreign Application Priority Data
Sep. 29, 2006 (JP) 2006-269085

(51) Int. Cl. C23C 16/00

(52) U.S. Cl. 118/726

(57) ABSTRACT

Disclosed is an evaporating apparatus for performing a film forming process on a target object to be processed by vapor deposition, wherein a processing chamber and a vapor generating chamber are disposed adjacent to each other, gas exhaust mechanisms for depressurizing an inside of the processing chamber and an inside of the vapor generating chamber are installed, a vapor discharge opening for discharging a vapor of the film forming material is disposed in the processing chamber, vapor generating units for vaporizing the film forming material and control valves for controlling a supply of the vapor of the film forming material are disposed in the vapor generating chamber, and flow paths, which are not exposed to an outside of the processing chamber and the vapor generating chamber, for supplying the vapor of the film forming material generated in the vapor generating units to the vapor discharge opening are installed.

### TECHNICAL FIELD

The present invention relates to an evaporating apparatus for performing a film forming process on a target object to be processed by vapor deposition.

### BACKGROUND ART

Recently, an organic EL device utilizing electroluminescence (EL) has been developed. Since the organic EL device generates almost no heat, it consumes lower power compared with a cathode-ray tube or the like. Further, since the organic EL device is a self-luminescent device, there are some other advantages, for example, a view angle wider than that of a liquid crystal display (LCD), so that progress thereof in the future is expected.

Most typical structure of this organic EL device includes an anode (positive electrode) layer, a light emitting layer and a cathode (negative electrode) layer stacked sequentially on a glass substrate to form a sandwiched shape. In order to bring out light from the light emitting layer, a transparent electrode made of ITO (Indium Tin Oxide) is used as the anode layer on the glass substrate. Such organic EL device is generally manufactured by forming the light emitting layer and the cathode layer in sequence on the glass substrate on the surface of which the ITO layer (anode layer) is preformed.

A vacuum deposition apparatus shown in Patent Document 1, for example, is known as an apparatus for forming the light emitting layer of such organic EL device.

### Patent Document 1: Japanese Patent Laid-open Publication No. 2000-282219

### DISCLOSURE OF THE INVENTION

### Problems to Be Solved by the Invention

However, in the process of forming the light emitting layer of the organic EL device, the inside of the processing chamber is depressurized to a preset pressure level during the vapor deposition process. The reason for this is that, when forming the light emitting layer of the organic EL device as described above, if the film formation is performed under the atmospheric pressure to deposit the film forming material on the surface of the substrate by supplying vapor of the film forming material of a high temperature of about 200° C. to 500° C. from an evaporating head, the heat of the vapor of the film forming material would be transmitted through the air inside the processing chamber to the various components such as sensors in the processing chamber. As a result, a temperature rise of such components and consequent deterioration of characteristics of the components or damage of the components themselves would be caused. Accordingly, in the process of forming the light emitting layer of the organic EL device, the inside of the processing chamber is depressurized to the preset pressure level in order to prevent the escape of the heat from the vapor of the film forming material (heat insulation by vacuum).

Meanwhile, a vapor generating unit for vaporizing the film forming material, a pipe for supplying the vapor of the film forming material generated in the vapor generating unit to the evaporating head, and a control valve for controlling a supply of the vapor of the film forming material are generally disposed outside the processing chamber in order to perform the replenishment of the film forming material, the maintenance thereof, and the like. However, if the vapor generating unit, the pipe and the control valve are disposed under the atmospheric pressure, the heat is radiated into the air, so that it is difficult to maintain a temperature of the vapor of the film forming material generated in the vapor generating unit at a desired level while the vapor is being sent to the evaporating head. For example, if a temperature of the vapor of the film forming material becomes below a set temperature while the vapor is being sent to the evaporating head, the film forming material is precipitated in the pipe or the like, so that the vapor can not be supplied sufficiently to the evaporating head. For this reason, the supply amount of the vapor from the evaporating head becomes reduced, thereby reducing a deposition rate. Further, since it is necessary to install a heater for preheating a carrier gas or for heating the pipe or the like in order to prevent such a temperature decrease, cost of the apparatus and running cost therefor increase and the size of the apparatus becomes large.

Therefore, an object of the present invention is to provide an evaporating apparatus capable of supplying the vapor of the film forming material generated in the vapor generating unit to the evaporating head without causing the temperature decrease.

### Means for Solving the Problems

In accordance with the present invention, there is provided an evaporating apparatus for performing a film forming process on a target object to be processed by vapor deposition, wherein a processing chamber for performing the film forming process on the target object and a vapor generating chamber for vaporizing a film forming material are disposed adjacent to each other, gas exhaust mechanisms for depressurizing an inside of the processing chamber and an inside of the vapor generating chamber are installed, a vapor discharge opening for discharging a vapor of the film forming material is disposed in the processing chamber, a vapor generating unit for vaporizing the film forming material and a control valve for controlling a supply of the vapor of the film forming material are disposed in the vapor generating chamber, and a flow path for supplying the vapor of the film forming material generated in the vapor generating unit to the vapor discharge opening without discharging it toward an outside of the processing chamber and the vapor generating chamber is installed.

It may be possible that an evaporating head, which has the vapor discharge opening formed at a surface thereof, is provided, and the evaporating head is supported by a partition wall which divides the processing chamber and the vapor generating chamber while the evaporating head's surface provided with the vapor discharge opening is exposed in the processing chamber. In this case, at least a part of the partition wall may be made of a thermal insulator. Further, the vapor generating unit and the control valve may support the evaporating head.

Furthermore, a carrier gas supply pipe for supplying a carrier gas, which supplies the vapor of the film forming material vaporized in the vapor generating unit to the vapor discharge opening, to the vapor generating mechanism may be provided. In this case, it may be possible that the vapor generating unit has a heater block which integrally heats an entire thereof, and disposed in the heater block are a material container which is filled with the film forming material and a carrier gas path for flowing the carrier gas supplied from the carrier gas supply pipe to the material container.

The film forming material is, for example, a film forming material for a light emitting layer of an organic EL device. Further, the control valve is, for example, a bellows valve or a diaphragm valve.

### EFFECT OF THE INVENTION

In accordance with the present invention, by supplying the vapor of the film forming material generated in a vapor generating unit to a vapor discharge opening without discharging it toward the outside of the processing chamber and the vapor generating chamber, it is possible to supply the vapor to the evaporating head under a state of heat insulation by vacuum without causing a temperature decrease. Therefore, precipitation of the film forming material in a pipe or the like can be prevented, so that the supply amount of the vapor from the evaporating head can be stabilized and a reduction of a vapor deposition rate can be avoided. Furthermore, since installation of a heater for heating the pipe or the like can be omitted, reduction of cost of the apparatus or running cost therefor can be achieved and the apparatus can be miniaturized.

Moreover, if the vapor generating unit and the control valve are supported on the evaporating head as one body, an evaporating unit can have a compact size, so that the temperature controllability and uniformity of the entire evaporating unit can be improved by maintaining the insides of the processing chamber and the vapor generating chamber under a state of heat insulation by vacuum. By integrating the vapor generating unit and the control valve with the evaporating head, there is no necessity for connecting portions of each component, so that a temperature decrease can be suppressed. In addition, since the evaporating unit can be taken out as one body, maintenance thereof is facilitated. Furthermore, if each of the vapor generating units 70, 71 and 72 is made of the heater block 91 capable of heating as a whole and the material container 92 and the carrier gas path 94 are disposed inside the heater block 91, a heater for preheating the carrier gas can also be omitted, so that the space can be saved.

### BRIEF DESCRIPTION OF THE DRAWINGS

FIG. 1 is a diagram for describing an organic EL device;

FIG. 2 is a diagram of a processing system;

FIG. 3 is a cross sectional view schematically illustrating a configuration of an evaporating apparatus in accordance with an embodiment of the present invention;

FIG. 4 is a perspective view of an evaporating unit;

FIG. 5 is a circuit diagram of the evaporating unit;

FIG. 6 is a perspective view of a vapor generating unit;

FIG. 7 is a diagram for describing a film formation system in which each processing apparatus is arranged around a transfer chamber;

FIG. 8 is a diagram for describing a processing system in which six processing apparatuses are arranged around a transfer chamber; and

FIG. 9 is a diagram for describing a processing system configured to directly load a substrate into respective processing apparatuses from a loading/unloading unit.

### EXPLANATION OF CODES

A: Organic EL device
G: Glass substrate
10: Processing system
11: Loader
12, 14, 16, 18, 20, 22: Transfer chambers
13: Evaporating apparatus for a light emitting layer
15: Film forming apparatus for a work function adjustment layer
17: Etching apparatus
19: Sputtering apparatus
21: CVD apparatus
23: Unloader
30: Processing chamber
31: Vapor generating chamber
32: Chamber main body
33: Partition wall
35, 40: Gas exhaust holes
36, 41: Vacuum pumps
45: Guide member
47: Substrate holding unit
55˜60: Evaporating units
65: Evaporating head
66: Pipe case
70˜72: Vapor generating units
75˜77: Control valves
80: Vapor discharge opening
81˜83: Branch pipes
85: Joint pipe
90: Heater
91: Heater block
92: Material container
93: Carrier gas supply pipe
94: Carrier gas path

### BEST MODE FOR CARRYING OUT THE INVENTION

Hereinafter, an embodiment of the present invention will be described in detail with reference to the accompanying drawings. In the following embodiment, a processing system 10 for manufacturing an organic EL device A by forming an anode (positive electrode) layer 1, a light emitting layer 3 and a cathode (negative electrode) layer 2 on a glass substrate G as a target object to be processed will be described in detail as an example of a vapor deposition process. Further, like reference numerals denote like parts through the whole document, and redundant description thereof will be omitted.

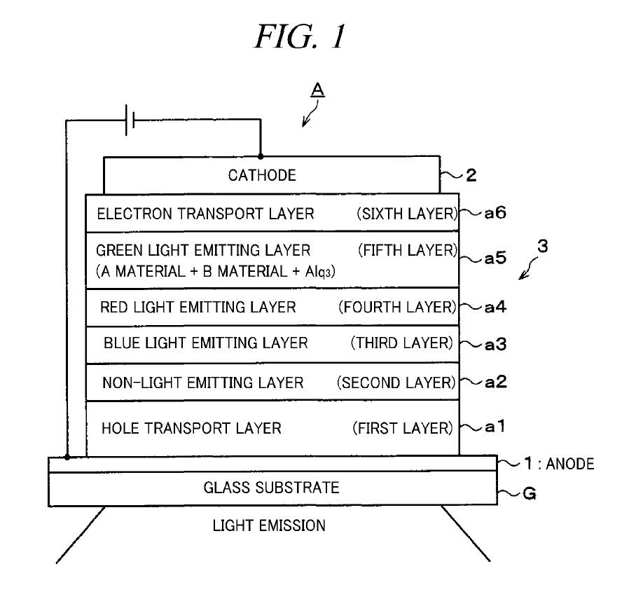

FIG. 1 provides a diagram for describing the organic EL device A manufactured in accordance with the embodiment of the present invention. The most typical structure of this organic EL device A is a sandwich structure in which the light emitting layer 3 is interposed between the anode 1 and the cathode 2. The anode 1 is formed on the glass substrate G. A transparent electrode made of, e.g., ITO (Indium Tin Oxide) capable of transmitting light of the light emitting layer 3 is used as the anode 1.

An organic layer serving as the light emitting layer 3 may be single-layered or multi-layered. In FIG. 1, it is a 6-layered structure having a first layer a1 to a sixth layer a6, layered on top of each other. The first layer a1 is a hole transport layer; the second layer a2 is a non-light emitting layer (electron blocking layer); the third layer a3 is a blue light emitting layer; the fourth layer a4 is a red light emitting layer; the fifth layer a5 is a green light emitting layer; and the sixth layer a6 is an electron transport layer. Such organic EL device A is manufactured through the processes of forming the light emitting layer 3 (i.e., the first layer a1 to the sixth layer a6) on the anode 1 on the surface of the glass substrate G in sequence; forming the cathode 2 made of Ag, an Mg/Ag alloy or the like, after interposing a work function adjustment layer (not shown) therebetween; and finally sealing the entire structure with a nitride film (not shown), as will be explained later.

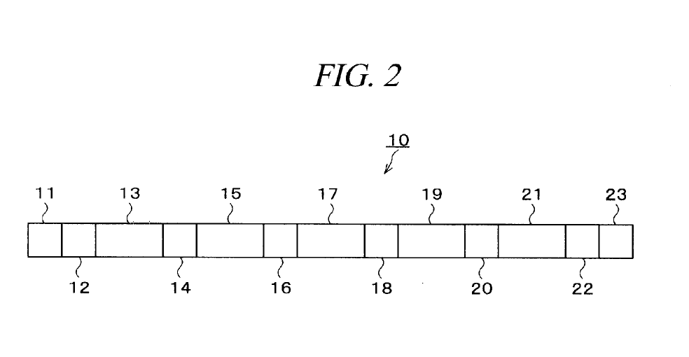

FIG. 2 illustrates a diagram describing the processing system 10 for manufacturing the organic EL device A. The processing system 10 has a configuration in which a loader 11, a transfer chamber 12, an evaporating apparatus 13 for the light emitting layer 3, a transfer chamber 14, a film forming apparatus 15 for the work function adjustment layer, a transfer chamber 16, an etching apparatus 17, a transfer chamber 18, a sputtering apparatus 19, a transfer chamber 20, a CVD apparatus 21, a transfer chamber 22 and an unloader 23 are sequentially arranged in series along a transfer direction (right direction in FIG. 2) of the substrate G. The loader 11 is an apparatus for loading the substrate G into the processing system 10. The transfer chambers 12, 14, 16, 18, 20 and 22 are apparatuses for transferring the substrate G between the respective processing apparatuses. The unloader 23 is an apparatus for unloading the substrate G from the processing system 10.

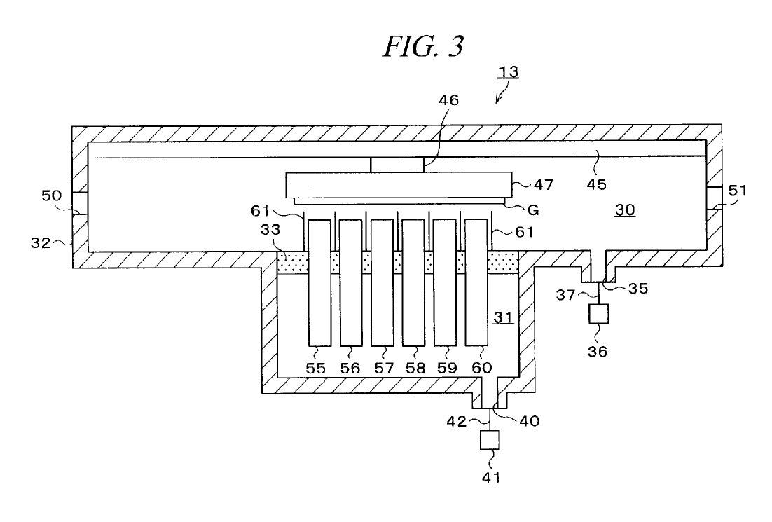

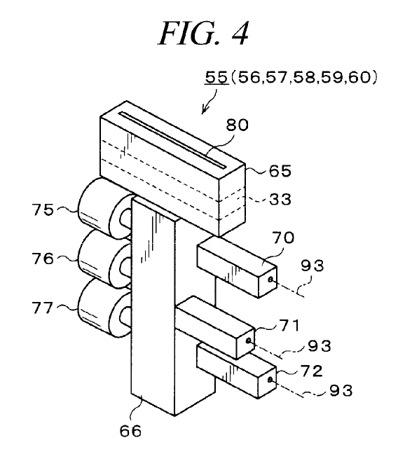

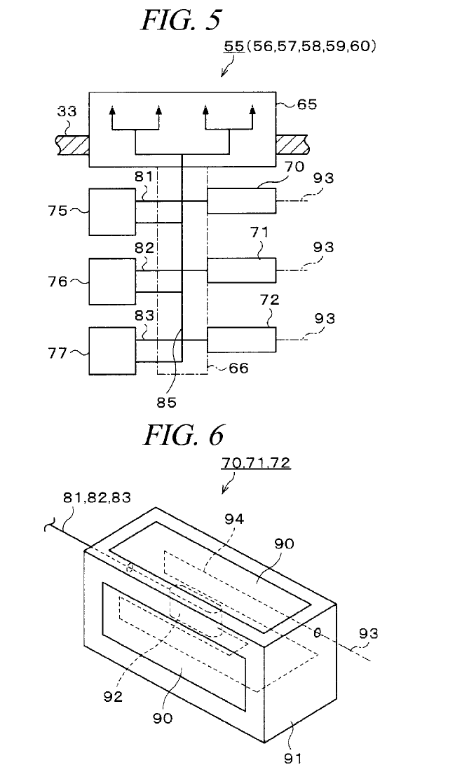

Hereinafter, the evaporating apparatus 13 in accordance with the embodiment of the present invention will be described in further detail. FIG. 3 is a cross sectional view schematically illustrating the configuration of the evaporating apparatus 13; FIG. 4 depicts a perspective view showing an evaporating unit 55 (56, 57, 58, 59 and 60) incorporated in the evaporating apparatus 13; FIG. 5 sets forth a circuit diagram of the evaporating unit 55 (56, 57, 58, 59 and 60); and FIG. 6 presents a perspective view of vapor generating units 70, 71 and 72.

The evaporating apparatus 13 has a configuration in which a processing chamber 30 for performing the film formation on the substrate G therein and a vapor generating chamber 31 for vaporizing a film forming material therein are vertically arranged adjacent to each other. The processing chamber 30 and the vapor generating chamber 31 are formed inside a chamber main body 32 made of aluminum, stainless steel, or the like, and the processing chamber 30 and the vapor generating chamber 31 are divided by a partition wall 33 made of a thermal insulator and provided therebetween.

A gas exhaust hole 35 is opened at the bottom surface of the processing chamber 30, and a vacuum pump 36, which serves as a gas exhaust mechanism and is disposed outside the chamber main body 32, is connected to the gas exhaust hole 35 via a gas exhaust pipe 37. The inside of the processing chamber 30 is depressurized to a preset pressure level by the operation of the vacuum pump 36.

Likewise, a gas exhaust hole 40 is opened in the bottom surface of the vapor generating chamber 31, and a vacuum pump 41, which serves as a gas exhaust unit and is disposed outside the chamber main body 32, is connected to the gas exhaust hole 40 via a gas exhaust pipe 42. The inside of the vapor generating chamber 31 is depressurized to a predetermined pressure level by the operation of the vacuum pump 41.

Installed at the top of the processing chamber 30 are a guide member 45 and a holding member 46 moving along the guide member 45 by an appropriate driving source (not shown). A substrate holding unit 47 such as an electrostatic chuck or the like is installed at the holding member 46, and the substrate G, which is the target of the film formation, is horizontally held on the bottom surface of the substrate holding unit 47.

A loading port 50 and an unloading port 51 are provided at side surfaces of the processing chamber 30. In the evaporating apparatus 13, the substrate G loaded from the loading port 50 is held by the substrate holding unit 47 and is transferred to the right side in the processing chamber 30 in FIG. 3 to be unloaded from the unloading port 51.

At the partition wall 33 dividing the processing chamber 30 and the vapor generating chamber 31, arranged along the transfer direction of the substrate G are six evaporating units 55, 56, 57, 58, 59 and 60 for supplying vapors of film forming materials. These evaporating units 55 to 60 include the first evaporating unit 55 for depositing the hole transport layer; the second evaporating unit 56 for depositing the non-light emitting layer; the third evaporating unit 57 for depositing the blue light emitting layer; the fourth evaporating unit 58 for depositing the red light emitting layer; the fifth evaporating unit 59 for depositing the green light emitting layer; and the sixth evaporating unit 60 for depositing the electron transport layer, and they deposit the vapors of the film forming materials in sequence onto the bottom surface of the substrate G while it is being transferred and being held by the substrate holding unit 47. Further, vapor division walls 61 are arranged between the respective evaporating units 55 to 60, so that the vapors of the film forming materials supplied from the respective evaporating units 55 to 60 are allowed to be deposited on the bottom surface of the substrate G in sequence without being mixed with each other.

Since all the evaporating units 55 to 60 have the same configuration, only the configuration of the first evaporating unit 55 will be explained as a representative example. As illustrated in FIG. 4, the evaporating unit 55 has a configuration in which a pipe case 66 is installed at the bottom side of an evaporating head 65, and three vapor generating units 70, 71 and 72 are disposed at one side of the pipe case 66 while three opening/closing valves 75, 76 and 77 are disposed at the opposite side.

A vapor discharge opening 80 for discharging the vapors of film forming materials for the light emitting layer 3 of the organic EL device A is formed in the top surface of the evaporating head 65. The vapor discharge opening 80 is provided in a slit shape along a direction perpendicular to the transfer direction of the substrate G and has a length equal to or slightly longer than the width of the substrate G. By transferring the substrate G by means of the substrate holding unit 47 while discharging the vapors of the film forming materials from this slit-shaped vapor discharge opening 80, a film can be formed on the entire bottom surface of the substrate G.

The evaporating head 65 is supported by the partition wall 33 for dividing the processing chamber 30 and the vapor generating chamber 31 while its top surface provided with the vapor discharge opening 80 is exposed to the inside of the processing chamber 30. The bottom surface of the evaporating head 65 is exposed to the inside of the vapor generating chamber 31. The pipe case (transport path) 66 installed at the bottom surface of the evaporating head 65 and the vapor generating units 70 to 72 and the control valves 75, 76 and 77 installed at the pipe case 66 are all located at the inside of the vapor generating chamber 31.

The three vapor generating units 70, 71 and 72 and the three control valves 75, 76 and 77 are in correspondence relationship. To elaborate, the control valve 75 controls the supply of the vapor of the film forming material generated from the vapor generating unit 70; the control valve 76 controls the supply of the vapor of the film forming material generated from the vapor generating unit 71; and the control valve 77 controls the supply of the vapor of the film forming material generated from the vapor generating unit 72. Installed in the inside of the pipe case 66 are branch pipes 81, 82 and 83 for connecting the respective vapor generating units 70 to 72 with the respective control valves 75 to 77, and a joint pipe 85 for mixing the vapors of the film forming materials supplied from the respective vapor generating units 70 to 72 via the respective control valves 75 to 77 and then supplying them to the evaporating head 65.

All the vapor generating units 70 to 72 have the same configuration. As shown in FIG. 6, each of the vapor generating units 70 to 72 has a heater block 91 provided with a plurality of heaters 90 on lateral sides thereof and capable of integrally heating the entire thereof. The entire heater block 91 is heated by the heaters 90 up to a temperature at which the film forming material can be vaporized.

Disposed at the center of the inside of the heater block 91 is a material container 92 which can be filled with the film forming material (vapor deposition material) for the light emitting layer 3 of the organic EL device A. The film forming material filled in the material container 92 is vaporized by the heat of the heater block 91. Further, a carrier gas supply pipe 93 for supplying a carrier gas such as Ar or the like is connected to a lateral side of the heater block 91. Inside the heater block 91, there is formed a carrier gas path 94 for providing the carrier gas supplied from the carrier gas supply pipe 93 to the material container 92 after flowing the carrier gas a sufficient distance around the inside of the heater block 91. Accordingly, the carrier gas supplied from the carrier gas supply pipe 93 is provided to the material container 92 after being heated up to a temperature nearly equal to the temperature of the heater block 91 by passing through the carrier gas path 94. Further, in case of replenishing the material container 92 with the film forming material, the inside of the vapor generating chamber 31 is first opened to the atmospheric atmosphere by a gate valve (not shown) or the like provided at a bottom portion of the chamber main body 32, and then, the material container 92 of each of the vapor generating units 70 to 72 is replenished with the film forming material. At this time, since the processing chamber 30 and the vapor generating chamber 31 are divided by the partition wall 33, the inside of the processing chamber 30 still remains depressurized and it is thermally insulated by vacuum even when the replenishment of the film forming material is carried out.

By performing the opening/closing operations of the respective control valves 75 to 77, it is possible to appropriately convert a state of supplying the vapors of the film forming materials, which are vaporized in the respective vapor generating units 70 to 72 and supplied via the respective branch pipes 81 to 83 along with the carrier gas, to the joint pipe 85 into a state of not supplying them, or vice versa. Bellows valves, diaphragm valves or the like can be employed as the control valves 75 to 77. By the opening/closing operations of the control valves 75 to 77, the vapors of the film forming materials vaporized in the respective vapor generating units 70 to 72 can be mixed in the joint pipe 85 in various ratios. The vapors of the film forming materials mixed in the joint pipe 85 are discharged from the vapor discharge opening 80 provided in the top surface of the evaporating head 65 without being exhausted to the outside of the processing chamber 30 and the vapor generating chamber 31. Further, though the first evaporating unit 55 has been explained as a representative example, other evaporating units 56 to 60 have the same configuration.

Besides, the film forming apparatus 15 for the work function adjustment layer as shown in FIG. 2 is configured to form the work function adjustment layer on the surface of the substrate G by vapor deposition. The etching apparatus 17 is configured to etch each formed layer. The sputtering apparatus 19 is configured to form the cathode 2 by sputtering an electrode material such as Ag or the like. The CVD apparatus 21 seals the organic EL device A by forming a sealing film made of a nitride film or the like by CVD or the like.

However, in the processing system 10 configured as described above, a substrate G loaded through the loader 11 is first loaded into the evaporating apparatus 13 through the transfer chamber 12. Here, the anode 1 made of, e.g., ITO is previously formed on the surface of the substrate G in a preset pattern.

In the evaporating apparatus 13, the substrate G is held by the substrate holding unit 47 while the substrate surface (film formation surface) faces downward. Further, before the substrate G is loaded into the evaporating apparatus 13, the insides of the processing chamber 30 and the vapor generating chamber 31 of the evaporating apparatus 13 are previously depressurized to preset pressure levels by the vacuum pumps 36 and 41.

Furthermore, in the depressurized vapor generating chamber 31, the vapors of the film forming materials vaporized in the respective vapor generating units 70 to 72 are mixed in the joint pipe 85 in a certain combination by the opening/closing operations of the control valves 75 to 77. Then, the vapors of the film forming materials are supplied to the evaporating head 65 without being exhausted out of the vapor generating chamber 31. Accordingly, the vapors of the film forming materials supplied to the evaporating head 65 is discharged from the vapor discharge opening 80 provided in the top surface of the evaporating head 65 in the processing chamber 30.

Meanwhile, in the depressurized processing chamber 30, the substrate G held by the substrate holding unit 47 is transferred to the right of FIG. 3. While the substrate G is moving, the vapors of the film forming materials are supplied from the vapor discharge openings 80 of the top surfaces of the evaporating heads 65, so that the light emitting layer 3 is formed/deposited on the surface of the substrate G.

Then, the substrate G on which the light emitting layer 3 is formed in the evaporating apparatus 13 is loaded into the film forming apparatus 15 through the transfer chamber 14. In the film forming apparatus 15, the work function adjustment layer is formed on the surface of the substrate G.

Subsequently, the substrate G is loaded into the etching apparatus 17 through the transfer chamber 16, and each formed film is shaped therein. Then, the substrate G is loaded into the sputtering apparatus 19 through the transfer chamber 18, and the cathode 2 is formed thereon. Thereafter, the substrate G is loaded into the CVD apparatus through the transfer chamber 20, and sealing of the organic EL device A is performed therein. The organic EL device A thus manufactured is unloaded from the processing system 10 through the transfer chamber 22 and the unloader 23.

In the above-described processing system 10, the vapors of the film forming materials generated in the vapor generating units 70 to 72 can be supplied to the vapor discharge opening 80 without being exhausted to the outsides of the processing chamber 30 and the vapor generating chamber 31, so that it is possible to send the vapors of the film forming materials to the evaporating head 65 without lowering the temperature thereof by maintaining them in the heat insulation state by vacuum. Therefore, precipitation of the film forming materials in the branch pipes 81, 82 and 83, the respective control valves 75 to 77, the joint pipe 85, and the like can be prevented, so that the supply amount of the vapors from the evaporating head 65 can be stabilized and a reduction of a vapor deposition rate can be avoided. Moreover, since installation of heaters for heating the branch pipes 81, 82 and 83, the respective control valves 75 to 77, the joint pipe 85, and the like can be omitted, cost of the apparatus or running cost therefor can be reduced, and miniaturization of the apparatus can also be possible.

Moreover, if the evaporating units 55 to 60, each having the pipe case 66, the vapor generating units 70 to 72 and the control valves 75, 76 and 77 installed as one body at the lower side of the evaporating head 65, are employed, each of the evaporating units 55 to 60 can be configured to have a compact size. Further, since each of the evaporating units 55 to 60 can be taken out as one body, maintenance thereof can also be facilitated.

Moreover, as shown in FIG. 6, if each of the vapor generating units 70, 71 and 72 is made of the heater block 91 capable of heating as a whole and the material container and the carrier gas path 94 are disposed inside the heater block 91, a heater for preheating the carrier gas can also be omitted, so that the space can be saved.

The above description of the present invention is provided for the purpose of illustration, and do not limit the present invention. It would be understood by those skilled in the art that all modifications and embodiments conceived from the meaning and scope of the claims and their equivalents are included in the scope of the present invention. For example, though the above description has been provided based on the evaporating apparatus 13 for the light emitting layer 3 of the organic EL device A, the present invention can also be applied to evaporating apparatuses for use in processes of various electronic devices.

The target substrate G to be processed may be various substrates such as a glass substrate, a silicon substrate, angled or annularly shaped substrates, or the like. Furthermore, the present invention is also applicable to a target object to be processed other than the substrate.

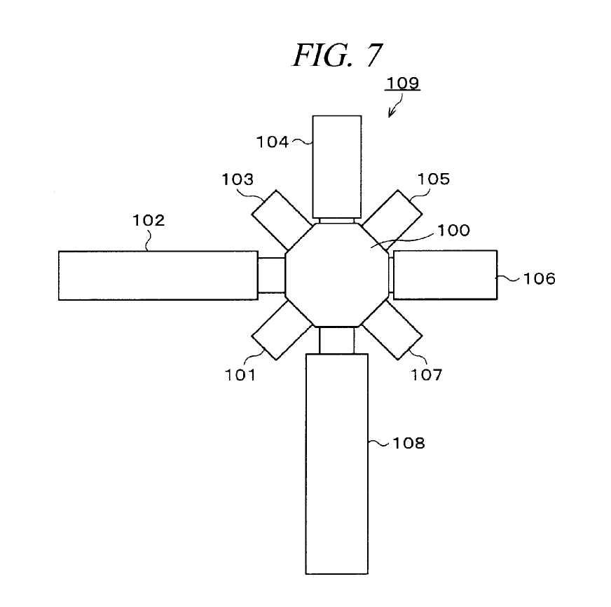

FIG. 2 illustrates the processing system 10 having the configuration in which the loader 11, the transfer chamber 12, the evaporating apparatus 13 for the light emitting layer 3, the transfer chamber 14, the film forming apparatus 15 for the work function adjustment layer, the transfer chamber 16, the etching apparatus 17, the transfer chamber 18, the sputtering apparatus 19, the transfer chamber 20, the CVD apparatus 21, the transfer chamber 22 and the unloader 23 are sequentially arranged in series along the transfer direction of the substrate G. However, as shown in FIG. 7, there may be employed a film formation system 109 having a configuration in which a substrate load lock apparatus 101, a sputtering-evaporating apparatus 102, an alignment apparatus 103, an etching apparatus 104, a mask load lock apparatus 105, a CVD apparatus 106, a substrate reverse apparatus 107, an evaporating apparatus 108 are arranged around a transfer chamber 100, for example. The number and arrangement of each processing apparatus may be varied.

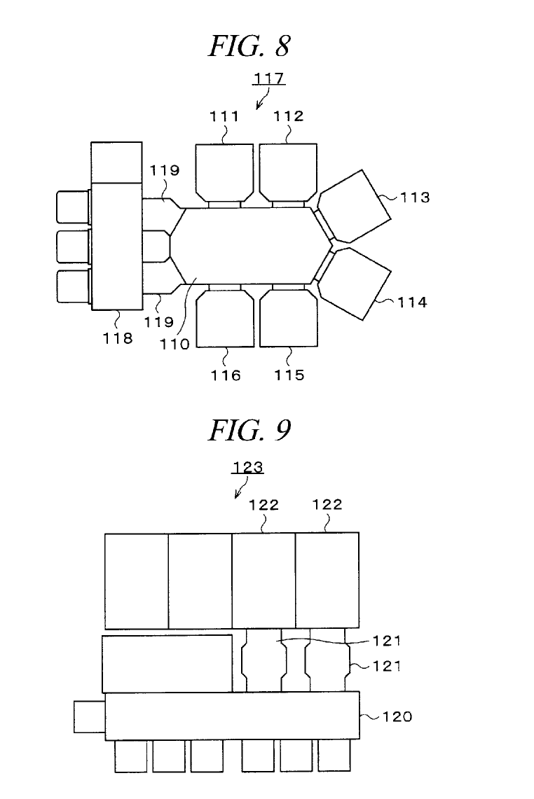

For example, as illustrated in FIG. 8, it is possible to apply the present invention to a processing system 117 in which six processing apparatuses 111 to 116 are arranged around a transfer chamber 110. Furthermore, in the processing system 117 illustrated in FIG. 8, the substrate G is loaded to or unloaded from the transfer chamber 110 through two load lock chambers from a loading/unloading unit 118 and the substrate G is loaded to or unloaded from the respective processing apparatuses 111 to 116 through the transfer chamber 110.

Further, for example, as illustrated in FIG. 9, it is also possible to apply the present invention to a processing system 123 in which the substrate G is directly loaded to or unloaded from respective processing apparatuses 122 and 122 (without passing through a transfer chamber) through a load lock chamber 121 from a loading/unloading unit 120. As stated above, the number and arrangement of processing apparatuses installed in the processing system may be varied.

In addition, in the above embodiment, the substrate G loaded into the processing chamber 30 from the loading port is unloaded from the unloading port 51 after it is processed in the evaporating apparatus 13. However, it may be also possible to install a loading/unloading port to be used as a loading port and an unloading port at the same time and to load the substrate G into the processing chamber 30 through the loading/unloading port and then to unload it through the loading/unloading port again after the processing is completed. Further, it is desirable to set up a transfer path through which the substrate G can be unloaded from the processing chamber 30 as soon as possible after the completion of the processing.

Moreover, the materials discharged from the evaporating head 65 of each of the evaporating units 55 to 60 may be same or different from each other. Further, the number of the evaporating units is not limited to six, but can be varied. In addition, the number of the vapor generating units or the control valves installed in the evaporating unit can be varied.

### INDUSTRIAL APPLICABILITY

The present invention may be applied to, e.g., a field of manufacturing an organic EL device.

1. An evaporating apparatus for performing a film forming process on a target object to be processed by vapor deposition,
wherein a processing chamber for performing the film forming process on the target object and a vapor generating chamber for vaporizing a film forming material are disposed adjacent to each other,
gas exhaust mechanisms for depressurizing an inside of the processing chamber and an inside of the vapor generating chamber are installed,
a plurality of evaporating units each supplying a vapor of the film forming material is supported by a partition wall dividing the processing chamber and the vapor generating chamber,
installed in each evaporating unit are a vapor discharge opening, disposed in the processing chamber, for discharging the vapor of the film forming material; a vapor generating unit, disposed in the vapor generating chamber, for vaporizing the film forming material; a control valve, disposed in the vapor generating chamber, for controlling a supply of the vapor of the film forming material; and a flow path, which is not exposed to an outside of the processing chamber and the vapor generating chamber, for supplying the vapor of the film forming material generated in the vapor generating unit to the vapor discharge opening, and
a vapor division wall is disposed between the evaporating units.

2. The evaporating apparatus of claim 1, wherein a holding member for holding and moving the target object is installed at an upper side of the processing chamber,
the plurality of evaporating units is arranged along a transfer direction of the target object, and
by the vapor division wall disposed between the evaporating units, the vapor of the film forming material supplied from each of the evaporating units is deposited on a bottom surface of the target object in sequence without being mixed with each other.

3. The evaporating apparatus of claim 1, wherein at least a part of the partition wall is made of a thermal insulator.

4. The evaporating apparatus of claim 1, wherein the evaporating unit is provided with a pipe case mounted below an evaporating head, and
the vapor generating unit and the control valve are installed at the pipe case.

5. The evaporating apparatus of claim 1, wherein a carrier gas supply pipe for supplying a carrier gas, which supplies the vapor of the film forming material vaporized in the vapor generating unit to the vapor discharge opening, to the vapor generating unit is provided.

6. The evaporating apparatus of claim 5, wherein the vapor generating unit has a heater block which integrally heats an entire thereof, and
disposed in the heater block are a material container which is filled with the film forming material and a carrier gas path for flowing the carrier gas supplied from the carrier gas supply pipe to the material container.

7. The evaporating apparatus of claim 1, wherein the film forming material is a film forming material for a light emitting layer of an organic EL device.

8. The evaporating apparatus of claim 1, wherein the control valve is a bellows valve or a diaphragm valve.
